(19) United States
(12) Patent Application Publication
(10) Pub. No.: US 2014/0352757 A1
(43) Pub. Date: Dec. 4, 2014

(54) Smart modular automated multi axis case for solar modules, panels, electronic displays, sensors, and the like

(71) Applicant: Johnny Ramirez, San Diego, CA (US)

(72) Inventor: Johnny Ramirez, San Diego, CA (US)

(21) Appl. No.: 13/999,747

(22) Filed: Mar. 18, 2014

Related U.S. Application Data
(60) Provisional application No. 61/852,151, filed on Mar. 15, 2013.

(51) Int. Cl. H01L 31/052

(52) U.S. Cl. CPC H01L 31/0522
USPC 136/246

(57) ABSTRACT

The present invention comprises a novel smart multi-axis rotating case for a variety of products and functions. It is meant to give people alternative ways in which to use solar power. In preferred embodiments, the present invention is a device such as a 2 axis dual pitch Tracking Case which may be a solar tracking case to track the rotation of the sun. Solar Trackers aren't generally known for being low profile light cases with handles that are easily portable and interchangeable from buildings yards ground mounts or vehicle roof or roof rack mounts. The device as described by examples herein is meant to provide individuals with a new evolved way of using solar power. This product also works well as a container filled with hundreds of units for mobile power deployment. With batteries and controlling hardware this product ships more solar power (more watts per sq. foot). Smaller embodiments of the device include a personnel portable mini model for use with back packs, briefcases, laptops, bikes, wagons, emergency vehicles and more. Current solar 2 axis solar trackers are generally bulky heavy slow machines that afford little flexibility and alternative capability. This device seeks new markets for alternative solar products that one can take with them in emergencies or camping and or remote work sites. A product that one could easily set up at home and then put on or in the family vehicle. Small travel pack arrays that fit in a van truck or car are another ideal application of the device. Currently available solar panels and Solar Trackers do not offer the capability and flexibility that the multi-axis rotating case as described herein does.

### APPENDIX

The present application contains an Appendix showing one non-limiting, working example of a prototype of the device according to some embodiments described herein. The working example shown should not be used to unintentionally limit the scope of the invention. The appendix is hereby incorporated by reference.

### BACKGROUND OF THE INVENTION

The present invention relates to the technical field of smart multi-axis rotating cases. More particularly, the present invention relates to the technical field of case rotating, multi-axis, trackers including solar case trackers. More particularly the present invention relates to the technical field of compact smart modular mobile multi-functional rotating cases.

This device as described herein is designed to improve tracking and multi axis rotating capabilities for solar panels and other components such as monitors, displays, coolers, fans, sensors, etc.. A compact low profile multi-axis rotating case (also known as “tracker” or the “device”) which may incorporate solar modules or solar panels and or other medias of various sizes and or proportions is what is represented by example in FIGS. 1 through 7. Efficiently minimizing a dual axis mechanical tracking system with economy in space yielding greater efficiencies comprising of a plurality of computer controlled electric motors housed in a very durable rubber polycarbonate composite case. In some preferred embodiments, when the case is in a closed position, it is configured to provide weather protection from the elements with sealed seams and high impact protection via a rubber perimeter, polycarbonate face, and composite rear panel. Solar Tracking devices are generally bulky awkwardly shaped devices with large heavy gears and slow moving motors that have not been refined simplified or compartmentalized enough to offer individual users maximized capability and mobility for home, commercial, roof ground, vehicle, 3^{rd} party product mount variations as well as domestic travel packs and industrial container array's. Solar trackers are not known for being light portable cases capable of being mounted on the roof of a car which may then be taken off and moved to your home roof or backyard warehouse etc. People don't associate 2 axis solar trackers as low profile cases they can stack in a van or car compartment for use at a camp site remote location etc. Also Flat 2 axis automated tracker cases are not currently used with display or sensor devices that can track a viewer. The modular multi-axis rotating tracking case combines maximized capability with economy in scalability affording manufacturing savings that hold current solar tracking products back from being cost effective. This multi-axis rotating case and System takes advantage of a very low profile “height” offering users more efficient solar power through sun tracking and more economy in weight size and engineering. Essentially a low profile mobile solar tracker for static and mobile applications, single unit and or large array configurations. In today's market place these ramifications as specified are currently not available in a compact hand held tracker case that comes in a range of sizes that are light weight and used in different applications and product.

Therefore, there is a great need in the field for a new type of modular automated, low profile, case for solar panels and the like.

### BRIEF SUMMARY OF THE INVENTION

A slim low profile smart multi-axis rotating modular case, scalable to various sizes proportions and functions is presented herein. In some embodiments, the device may be the slimmest lightest dual axis case or tracker (sometimes “solar tracker”) comprising of dual pitch frames housed in a case designed for a variety of tracking or other rotating application. Combining multi mount locking capabilities for static, mobile, ground, vehicle, and roof mounts for homes, yards, farms, warehouses as well as travel packs in vehicles or containers for small and large array deployments hand held to vehicle and building mount. Maximizing automated solar tracking variable axis capabilities by efficiently minimized housing and mechanical architecture.

### BRIEF DESCRIPTION OF THE DRAWINGS

FIG. 1 shows an example of a multi-axis rotating case compartmentalized in its closed portable position

FIG. 2 illustrates an example of a multi-axis rotating case in its first open position with attached protective rear underside cover.

FIG. 3 illustrates an example of a multi-axis rotating case rotating away from its first open position, showing continuous 360 degrees of capability.

FIG. 4 illustrates the back underside of an example of a multi-axis rotating case in its first open position with no back cover showing some of the structural and mechanical components.

FIG. 5 shows a plan view of an example of a base of the case in its closed position.

FIG. 6 demonstrates a side section view representing various relationships and configurations of the device in a closed and open position.

FIG. 7 illustrates an example of alternative media displays and or sensors for viewer and object tracking, analysis, advertising etc. and the like.

FIG. 8 represents smart case units in entirety. Sizes mentioned but not limited to Micro, Mini (Handheld) and Convertible portable vehicle & mountable units

### DETAILED DESCRIPTION AND BEST MODE OF IMPLEMENTATION

Some embodiments of the present invention are illustrated as an example and are not limited by the figures of the accompanying drawings, in which like references may indicate similar elements (numbers shown in list below) and in which the device may include:

1 Solar panel

2 Mounting and locking mechanism

3 Inset handles

4 Top of case

5 Bottom of case

6 Shroud cover

7 Base frame

8 Ring frame

9 Rotation frame

10 Rotation motor, front or back

11 Side frame stabilizer

12 Stabilizer axle wheel

13 Pitch actuator

14 Actuator front axle

15 rear actuator axle

16 Actuator arm

17 Pitch frame

18 front pitch lift arm

19 rear pitch lift arm

20 Front slide axle bracket

21 Rear pitch axle

22 PV frame

23 Rear pitch arm pivot bracket

24 Plug in ports

25 Optional inverter

26 Ground plate brackets storage bin

27 PV junction box

28 Pancake slip ring

29 bearing rotation plate

30 Rear actuator axle frame

31 Rear axle frame connection

32 Emergency rear axle release

33 Main rotation axle

34 Front lift arm axle

35 Rear lift arm axle

36 Optional heating element

37 Standard mount brackets

38 Ground mount plates

39 Electronic display

40 Sensors

41 PV axle hinge

42 Case tracker

43 Stationary mounts

44 Smart multi function ports, power, information 3^{rd} party product etc. . . .

45 Smart back-up cases Multi Function application not limited to Micro, Mini (handheld) and Convertible portable, vehicle, building mountable.

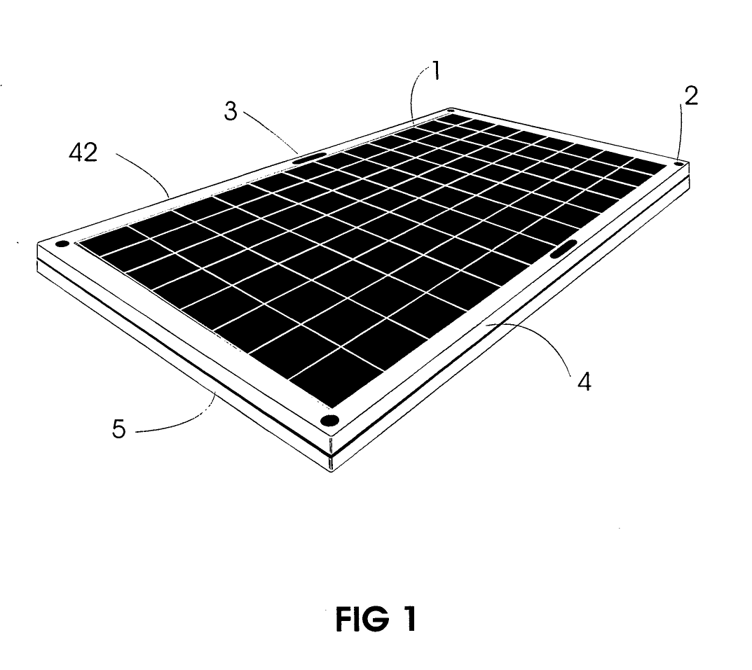

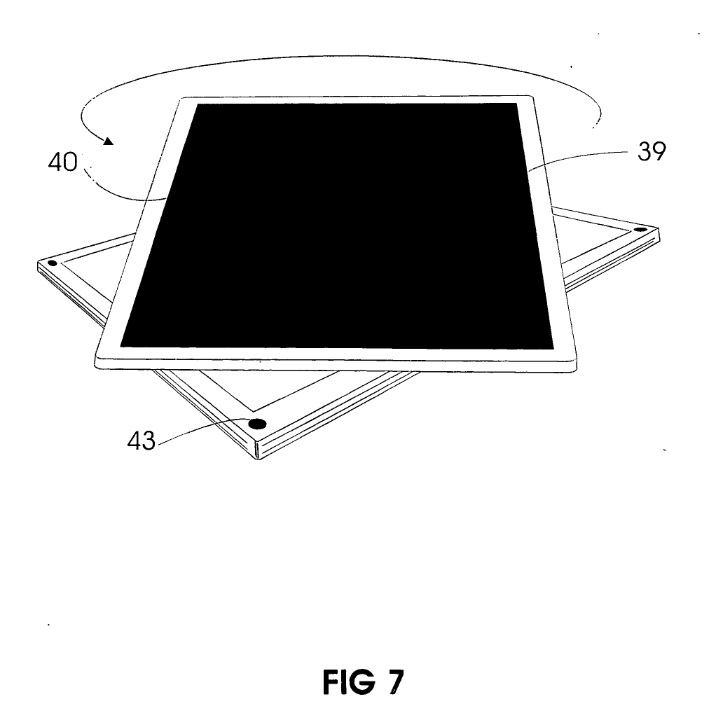

The present invention comprises a novel, low profile smart modular multi-axis rotating case and mounting system for solar panels, display screens, and the like (also known as the “device”). The present disclosure comprises examples of various embodiments illustrated in FIGS. 1 through 7 showing a 2 part durable low profile compact case housing comprising of a 2 axis automated tracker used to track the sun or rotate to a desired orientation. Incorporating a more efficient dual lift pitch frame working in conjunction with other main frames that have been reduced and compartmentalized to achieve the device's improved functionality. Capable of being used with a variety of products other than solar panels, FIG. 7 represents an example of the device as both an electronic display 39 for entertainment, computing, advertising and or sensors 40 but other types of equipment or objects may be used on the device as well. With inset handles 3 for ease of mobility, mounting and locking mechanisms 2 are at corners for locking and multi-application capability. The users have a plurality of options for ground, building, vehicle mounts and array configurations, static and mobile applications. Also housed are plug in ports 24 and ground plate brackets storage bin 26 for different mounting hardware.

FIG. 1. shows one example of a device (sometimes called “case tracker”) 42 with solar panel 1 which may be built in and PV frame 22 under panel 1 in the top of case top 4 with a compact tracking frame assembly and motors in bottom of case 5 all in a case closed position. Enclosed is a durable weather tight impact resistant housing for protecting solar panel 1 and compact mechanical frames motors and electronic systems. Housing adds longevity from weather, transport and storage. In some embodiments, the case comprises UV molded rubber around the perimeter top and bottom inner edges. The panel may have a clear UV coated polycarbonate coating with retainers and the rear bottom may be constructed with aluminum with a durable clear anodized or brushed finish. Optional inset handles 3 add ease of mobility and may be part of the rubber perimeter for protection and comfort. The mounting and locking mechanisms 2 at corners provide ability to easily switch locations and application of case from house yard or roof to a vehicle roof and or roof rack. The lock may be in one of the corner mounting holes or in other desirable locations. Solar panel 1 will generate power in both closed and open positions. In some embodiments, the device may be configured for vehicle applications (e.g. to be mounted onto the roof of vehicles). In preferred embodiments, the device may be mounted onto roofs of houses, buildings, or other suitable locations.

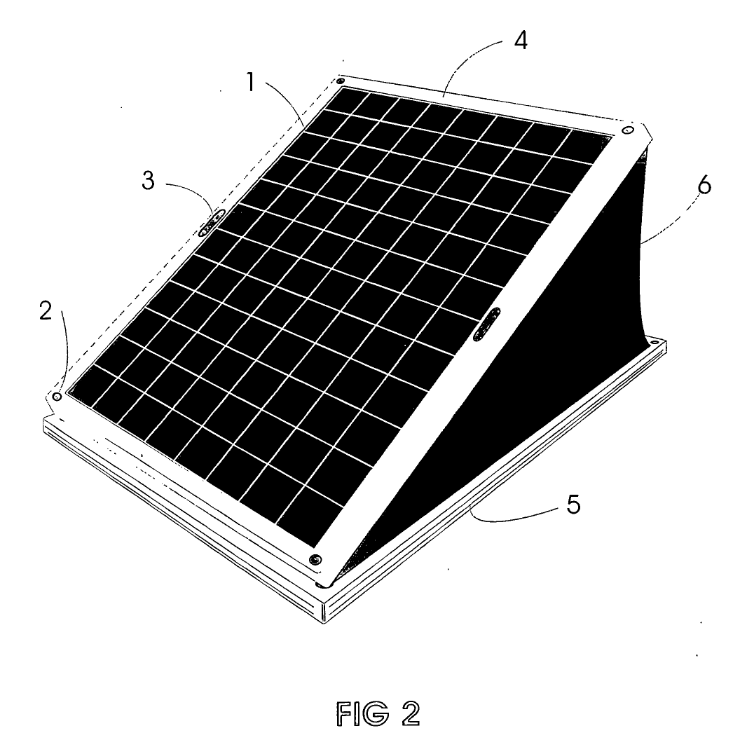

FIG. 2 is an example of the case tracker 42 in its first open position and represented in black behind and under the solar panel is the shroud cover 6 which provides weather protection when open. The example shown comprises a cover 6 made from an elastic high quality material such as nylon with a metal ring attached (similar to a window shade). The metal ring provides coil ability to expand and retract. In other embodiments, hard composite plastic segmented for raising and lowering may be used as the cover 6. The case tracker 42 is meant to be affixed when in operation with either ground mount plates, roof rack mounts or several other mount designs for building roofs and third party products.

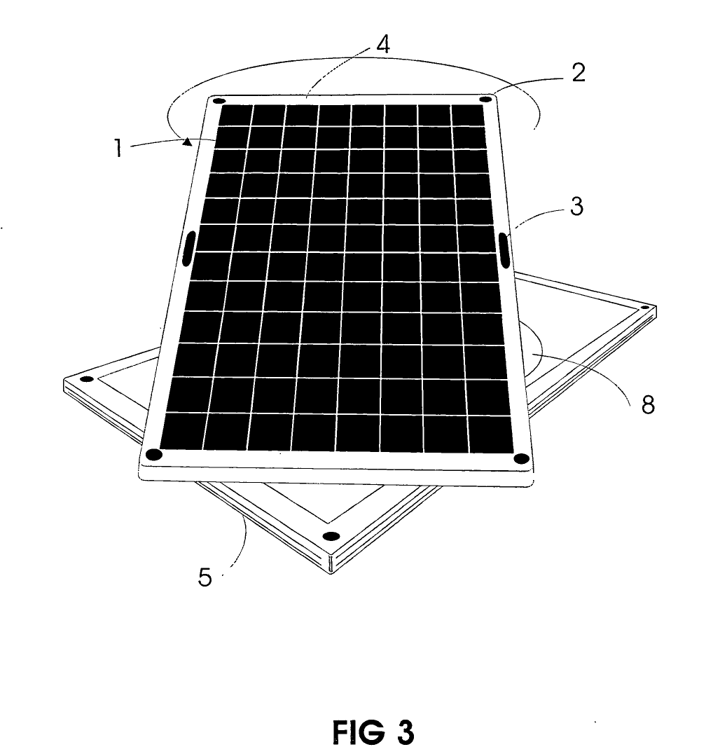

FIG. 3 is an example of the case tracker's 42 ability to turn 360 degrees continuously. In the example shown, the device comprises a ring frame 8 which omits more material while yielding stronger support at perimeters. It was apparent in testing that the device needed a 360 degree stabilizer system. The side frame stabilizers 11 and stabilizer axle wheels 12 may be added within the rotation frame 9. The device may be constructed from a variety of suitable materials including a combination of composite materials like Carbon Fiber or Plexiglas along with Aluminum and Stainless Steel or stronger for axles.

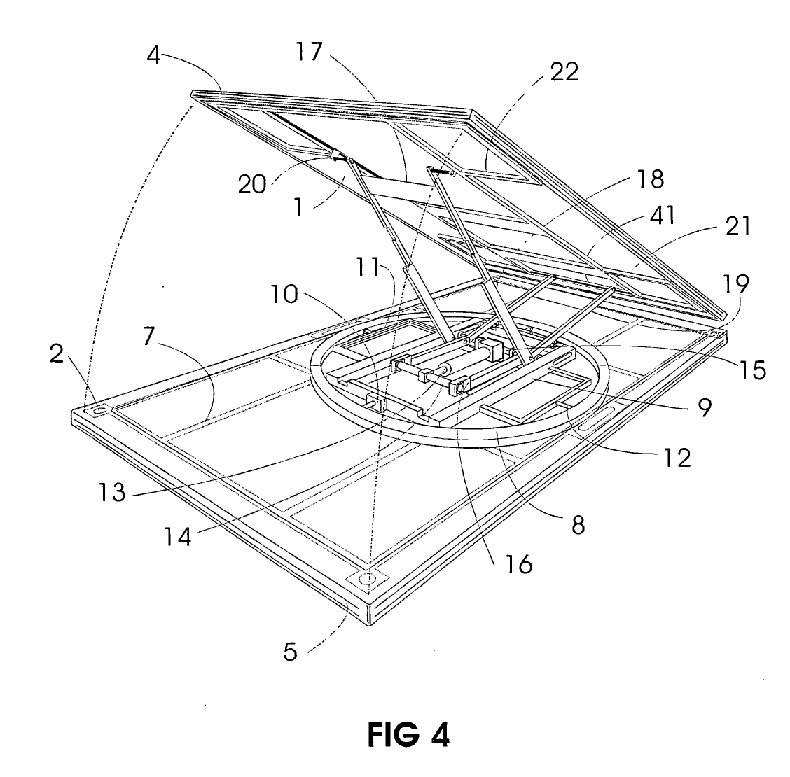

FIG. 4 is a view showing an example of the device from the rear in a first open position representing examples of the mechanical relationships and components. From the bottom up with the shroud 6 omitted the base frame 7 incorporating the ring frame 8 which supports the rotation frame 9 through front back and side frame stabilizers 11. The rotation frame 9 supports the pitch frame 17 which incorporates front and rear pitch arms. The front pitch lift arm 18 then connects to the PV frame 22 through the front slide axle brackets 20. In some embodiments a sliding rotational bracket that is located at the front of the panel in its home fold down position may be used. As the front and rear lift arms rotate up the slide axle brackets 20 slides back changing the load characteristics transmitted through the pitch lift arms 18, 19. The rear pitch lift arms 19 work differently by pivoting off the rear of the rotational frame via the rear pitch arm pivot bracket 23. This gives leverage to help with loads as well as changing the rate of lift. The rear lift arms 19 are connected to the PV frame 22 via the PV axle hinge 41. In preferred embodiments, the rear lift arms 19 are configured to slide back towards the center as the rotation is increased from the main rotation axle 33. The slide forward is going to be at the rear pitch arm pivot brackets 23. This is meant to raise top of case 4 clear from the bottom of case 5 allowing for 360 degree rotation.

The actuator 13 in the center of the rotation frame 9 has about 2″ of travel in this embodiment, extending its force forward through the actuator front axle 14 then through the actuator arms 16 which then rotate the front and rear pitch lift arms 18 and 19 via a central main rotation axle 33. The rear portion of the actuator is locked into the rear actuator axle frame 30 via the rear actuator axle 15. The actuator will pitch up approximately 2 to 5 degrees as it pushes its force forward pivoting off the rear actuator axle 15. In some embodiments, the parts and components described herein may be custom formed from composite materials or from stock aluminum shapes, this decision may vary according to fluctuating market prices and availability. In preferred embodiments, the rear actuator axle frame 30 is configured so that in case the pitch actuator 13 fail or something stops the up and down movement from happening, an emergency release is provided where the rear actuator axle frame 30 connects to the rotation frame 9. This part is called emergency rear axle release 32 which is connected by the rear axle frame connection 31. In some preferred embodiments, at the center rotation point a bearing rotation plate 29 is accompanied by a pancake slip ring 28 at dead center for transmitting power from top to bottom as well as bottom to top.

In some preferred embodiments, the multi-axis rotating case comprises a unique dual-lift feature allowing the case to move in multi-axis orientations. The dual lift feature is made possible by pivoting off the main rotation axle 33 the force of the pitch actuator 13 lifts both front and rear and front pitch lift arms 18,19. The main difference being that the rear pitch lift arm pivots as well as slides forward off the rear pitch arm pivot bracket 23 this assembly allows the rear pitch lift arms to bring the back of the top of the case low end down and forward to center as it is also lifts said panel at a greater rate on the high side. The rear pivot bracket 33 also rests on the rotation frame 9 which differs some loads that would otherwise be displaced by the pitch actuator 13.

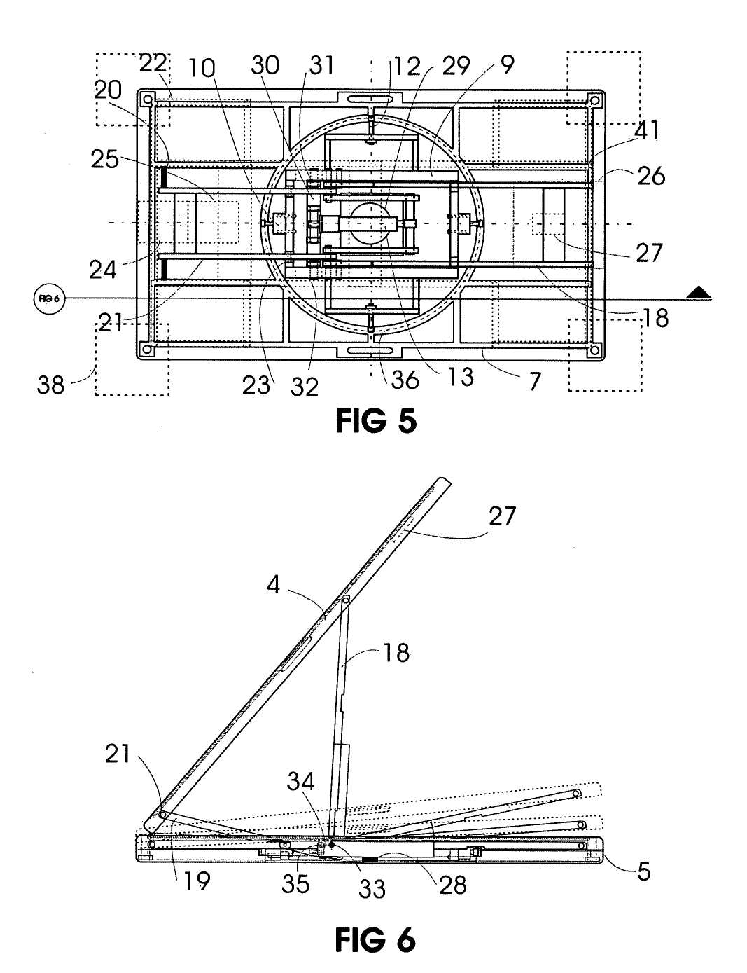

FIG. 5 is plan view of the base presenting examples of frame axle relationships and components. There is a section mark showing were FIG. 6 starts its side elevation view. The emergency rear axle release 32 is represented with dotted lines to signify a void that will be in the rotation frame 9 for releasing the mechanism. Other features represented in FIG. 5 show the location of plug in ports 24 with relation to optional on board inverter 25. On the opposing side the PV junction box 27 is represented along with a ground plate brackets storage bin 26. Ground mount plates 38 are represented as dotted lines at the corners. Also incorporated will be an optional heating element 36 for operation in Arctic or other cold winter conditions. This optional heating element wire, coil or cable may also wrap around the perimeter of the case tracker 42 and or shroud cover 6.

FIG. 6 shows a side view of the device and examples of various open and closed positions along with corresponding rotational pivot relationships. The main rotational axle 33 is designated in black and is the bases for rotation and lift for the front pitch lift arms 18 and rear pitch lift arms 19. The fully extended position is a good representation of the clearance the bottom case 5 has from the top of case 4.

FIG. 7 is an example of alternative embodiments and functions of the device which can serve as a case and mount for electronic monitors or display screens 39, light and radio wave or other types of sensors 40 or other components such as cameras, signs, energy, thermo, solar, wind devices and or other technologies thereof. The multi functionality is open to interpretation and like anything else will grow and evolve. This as key to what this product really is, at its core it's a 2 axis tracker case with a dual lift pitch frame 17 used for solar tracking.

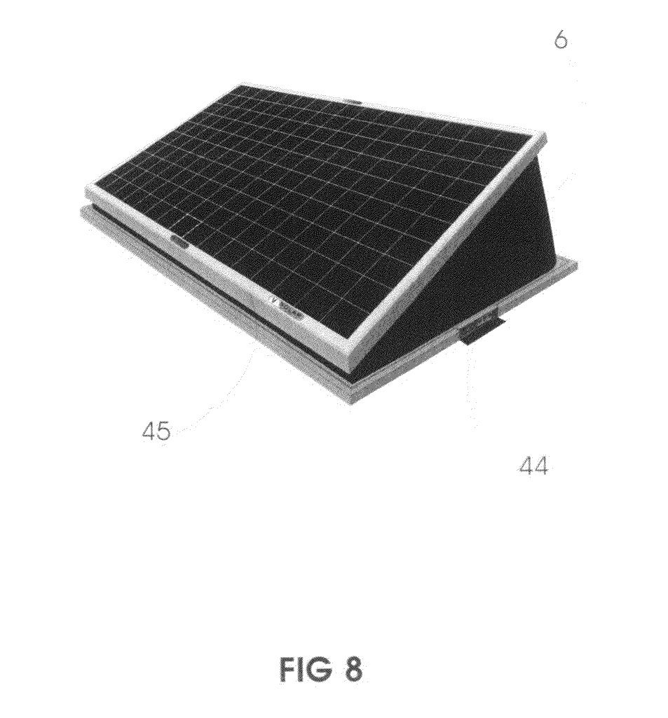

FIG. 8 Represents a fully enclosed unit in it's first open location. 44 shows Smart multi function ports for power, information and other 3^{rd} party product and or capabilities, the like . . . 45 Smart Back-up Cases in their entirety Multi Function applications and capabilities not limited to Micro, Mini (handheld) and Convertible portable, vehicle, building mountable units.

### NON-LIMITING EXAMPLE

The multi-axis rotating case may be constructed of any suitable size and dimensions, however, in some preferred embodiments the case is of low-profile design which generally means the case has a height from 2.5″ to 4″ but more preferably from 1″ to 2.75″.

I claim:

1. An automated smart multi-axis rotating case for solar panels and the like with a compact design and water tight closed sealing ability and modular mount systems for ground, building, and vehicle applications comprising:
a sealed impact resistant case with built in 2 axis rotating mechanisms, components, devices, and electronics.

2. The case of claim 1 further comprising dual pitch and rotational frames and or mechanical mechanisms and electronics specific to lift portions of the device and rotational activation for a plurality of applications such as electronic displays, cameras, sensors, signs, energy, thermo, solar, wind devices and or other technologies thereof.

3. The case of claim 1 further comprising multi-axis pitch rotation frames which has a plurality of arms to convey the force of an actuator that lifts opposing sides of a top panel of case system simultaneously at different increments so as to enable unimpeded activation of 360 degree rotation of case top for optimal surface normal angles to points of reference like the sun conveyed through a plurality of motors.

4. The case of claim 1 further comprising solar panels or components of various sizes and proportions comprising of numerous PV panels and or components housed in a durable protective water tight casing with inset handles and a plurality of mounting devices for improved applications and smart capability to be mounted for mobile or stationary applications wherein the case has a more efficient low profile height for compartmentalization and offers improved mounting, storage, and travel feature and capabilities.
